(19) United States
(12) Patent Application Publication
(10) Pub. No.: US 2009/0323301 A1
(43) Pub. Date: Dec. 31, 2009

(54) AUTOMOTIVE RELAY SYSTEM

(75) Inventors: Michael Gibbons, Garden City, MI (US); Christopher J. Darr, Livonia, MI (US); Gary Boothroyd, Farmington Hills, MI (US)

Correspondence Address: BROOKS KUSHMAN P.C. / LEAR CORPORATION, 1000 TOWN CENTER, TWENTY-SECOND FLOOR, SOUTHFIELD, MI, 48075-1238, US

(73) Assignee: LEAR CORPORATION, Southfield, MI (US)

(21) Appl. No.: 12/145,573

(22) Filed: Jun. 25, 2008

(51) Int. Cl. H05K 7/00

(52) U.S. Cl. 361/819

(57) ABSTRACT

An integrated relay system includes an automotive relay and a terminal interface. The automotive relay includes switching contacts and a casing. The casing at least partially surrounds the switching contacts and includes an aperture. The terminal interface is electrically connected with at least one of the switching contacts and is configured to receive a portion of a fuse. The terminal interface also passes through aperture and extends away from the casing.

### BACKGROUND

1. Field

Embodiments of the invention relate to automotive relay systems.

2. Discussion

A relay is an electrical switch that opens and closes under the control of another electrical circuit. In some relays, if a current flows through a coil, the resulting magnetic field attracts an armature that is mechanically linked to a moving contact. This movement may either connect or disconnect a connection with a fixed contact. If the current to the coil is switched off, the armature is returned by a force to its relaxed position. A spring or gravity may supply this force.

If the coil is to be energized with direct current, a resistor may be electrically connected across the coil. Upon deactivation, this resistor may dissipate energy—which may otherwise generate a voltage spike—from the collapsing magnetic field. Some automotive relays having a casing may include this resistor inside the casing. Alternatively, a capacitor and resistor in series may be configured to absorb/dissipate this energy.

If the coil is to be energized with alternating current, a copper ring may be crimped to an end of a solenoid. This ring may create an out-of-phase current that increases the minimum pull on the armature during the alternating current cycle.

Certain relays are designed to operate quickly. This may reduce noise in low voltage applications and reduce arcing in high voltage or high current applications.

FIG. 1 is a schematic view, in cross-section, of a prior art automotive printed circuit board relay 10. The relay 10 includes a switch/contacts 12 and a coil 14 disposed within a housing 16. An electrical potential applied to the coil 14 creates an electromagnetic field that actuates the switch 12.

The switch/contacts 12 includes electrical connector pins 18, 20 that protrude through the housing 16. The coil 14 includes electrical connector pins 22, 24 that also protrude through the housing 16. The connector pins 18, 20, 22, 24 may be attached to a printed circuit board (not shown).

FIGS. 2A and 2B are side and plan views respectively of a prior art printed circuit board assembly 26. The assembly 26 includes a printed circuit board 28, the relay 10, forked terminals 30, 32 and a fuse 34. The relay 10 is attached, e.g., soldered, to the printed circuit board 28. The forked terminals 30, 32 are positioned next to the relay 10 and are also attached to the printed circuit board 28. The forked terminal 30 is electrically connected with the connector pin 18. The forked terminal 32 may be electrically connected with a power source (not shown).

Blades 35 of the fuse 34 are retained by prong portions 36, 38 of the forked terminals 30, 32 respectively. The fuse 34 protects the relay 10 and any downstream components from spikes in electrical current.

### SUMMARY

An integrated relay system includes an automotive relay and a terminal interface. The automotive relay includes switching contacts and a casing. The casing at least partially surrounds the switching contacts and has a surface defining an aperture. The terminal interface is electrically connected with at least one of the switching contacts and is configured to receive a portion of a fuse. The terminal interface extends through the aperture and away from the casing.

The terminal interface may comprise a female terminal.

The female terminal may include a pronged portion to retain the portion of the fuse and a shoulder portion adjacent to the casing to support the pronged portion.

A printed circuit board assembly includes a printed circuit board and a plurality of integrated relay systems attached with the printed circuit board. Each of the plurality of integrated relay systems includes an automotive relay and at least one terminal interface. The automotive relay includes (i) switching contacts electrically connected with the first printed circuit board and (ii) a casing at least partially surrounding the switching contacts. The casing has a surface defining an aperture. The at least one terminal interface is electrically connected with at least one of the switching contacts and is configured to receive a fuse. The at least one terminal interface passes through the aperture and extends away from the casing.

The assembly may further include a plurality of fuses. Each of the fuses may be electrically connected with at least one of the terminal interfaces.

A printed circuit board assembly includes first and second printed circuit boards, a fuse and an integrated relay system. The integrated relay system includes an automotive relay having (i) switching contacts electrically connected with the first printed circuit board and (ii) a casing at least partially surrounding the switching contacts and having a surface defining an aperture. The integrated relay system also includes a first terminal interface electrically connected with at least one of the switching contacts and configured to receive a portion of the fuse. The first terminal interface extends through the aperture and away from the casing. The second printed circuit board includes a surface defining an opening configured to receive the first terminal interface. The first terminal interface extends though the opening. The assembly also includes a second terminal interface attached to the second printed circuit board and configured to receive another portion of the fuse. The fuse is connected with the first and second terminal interfaces.

The assembly may further include an electrical bus bar electrically connected with at least one of the terminal interfaces.

While example embodiments in accordance with the invention are illustrated and disclosed, such disclosure should not be construed to limit the invention. It is anticipated that various modifications and alternative designs may be made without departing from the scope of the invention.

### BRIEF DESCRIPTION OF THE DRAWINGS

FIG. 1 is a schematic view, in cross-section, of a prior art automotive printed circuit board relay;

FIG. 2A is a side view of a prior art printed circuit board assembly;

FIG. 2B is a plan view of the prior art printed circuit board assembly of FIG. 2A;

FIG. 3 is a schematic view, in cross-section, of an embodiment of an integrated relay system;

FIGS. 4A and 4B are schematic diagrams of portions of alternative embodiments of integrated relay systems;

FIG. 5 is a perspective view of an embodiment of an automotive printed circuit board assembly; and

FIG. 6 is a exploded assembly view of another embodiment of an automotive printed circuit board assembly.

### DETAILED DESCRIPTION

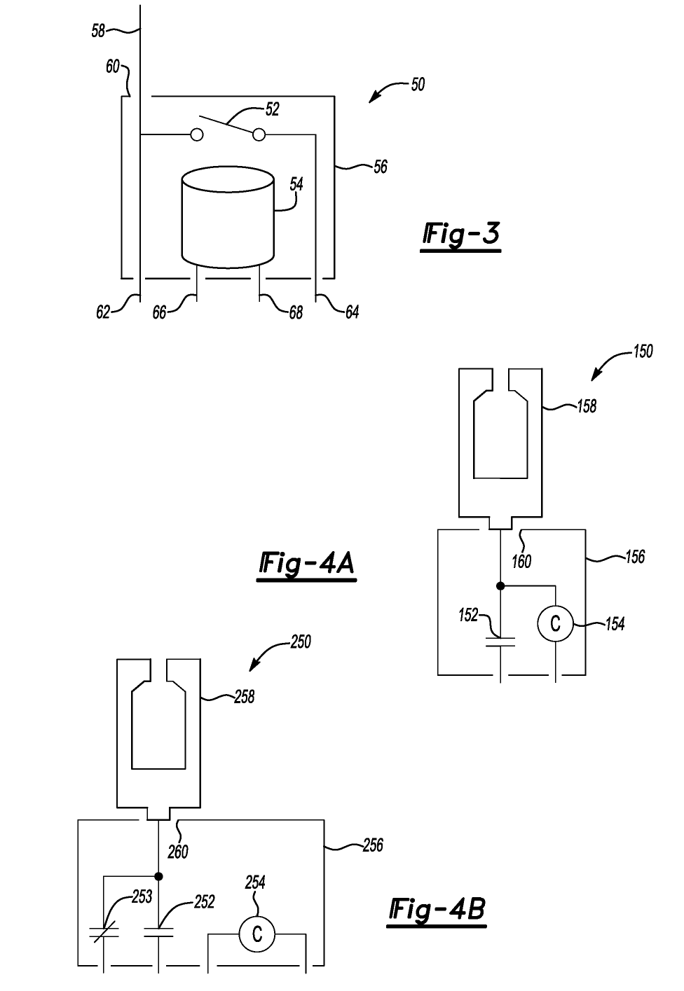

Referring now to FIG. 3, an embodiment of an integrated relay system 50 may include a switch/contacts 52 and a coil 54 disposed within a housing 56. An electrical potential applied to the coil 54 creates an electromagnetic field that actuates the switch/contacts 52. The system 50 may also include an interface terminal 58, e.g., a forked terminal, box terminal or any other female (or male) terminal. As known to those of ordinary skill, a forked terminal is a female terminal configured to receive a blade of a fuse. The interface terminal 58 is electrically connected with the switch/contacts 52 and protrudes through an opening 60 in the housing 56. As explained below, the interface terminal 58 is configured to receive and/or retain a fuse (not shown) of any suitable configuration.

The switch/contacts 52 include electrical connector pins 62, 64 that protrude through the housing 56. The coil 54 includes electrical connector pins 66, 68 that also protrude through the housing 56. The connector pins 62, 64, 66, 68 may be attached, e.g., soldered, etc., to a printed circuit board (not shown).

In the embodiment of FIG. 3, the interface terminal 58 extends normally away from a surface of the housing 56 opposite the connector pins 62, 64, 66, 68. The interface terminal 58, however, may protrude through and/or extend away from any suitable surface of the housing 56. In other embodiments, additional interface terminals 58 may be electrically connected with the switch/contacts 52 and pass through the opening 60 or additional openings (not shown) in the housing 56. In such embodiments, the interface terminals 58 may be located on a same side or different sides of the housing 56.

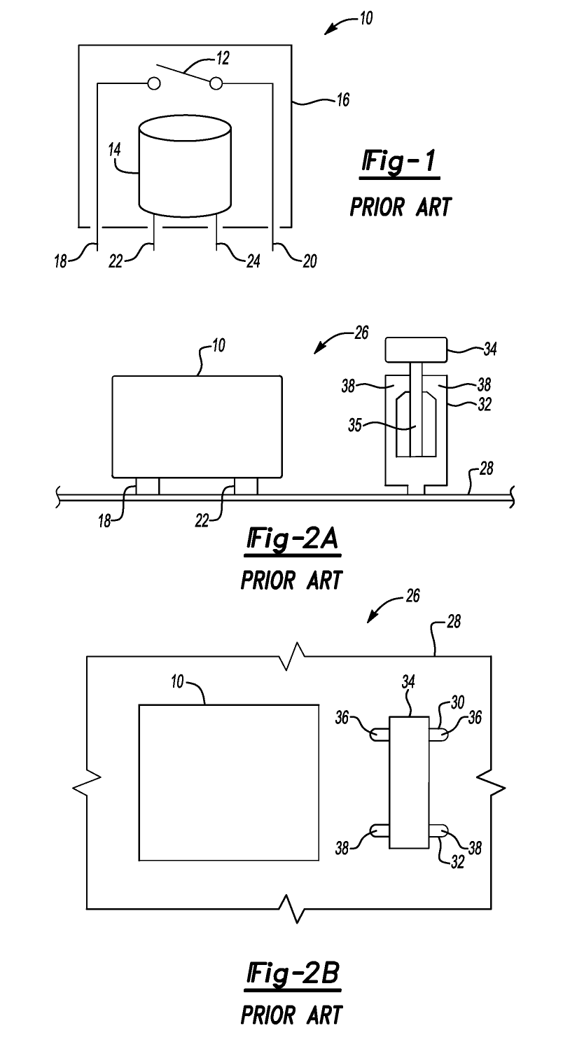

Referring now to FIG. 4A, numbered elements that differ by 100 relative to the numbered elements of FIG. 1 have similar, although not necessarily identical, descriptions to the numbered elements of FIG. 1. An embodiment of an integrated relay system 150 includes a switch/contacts 152, coil 154 and terminal interface 158. The coil 154 is electrically connected with the switch/contacts 152 and terminal interface 158.

Referring now to FIG. 4B, numbered elements that differ by 200 relative to the numbered elements of FIG. 1 have similar, although not necessarily identical, descriptions to the numbered elements of FIG. 1. An embodiment of an integrated relay system 250 includes switches/contacts 252, 253, a coil 254 and terminal interface 258. The switch/contacts 253 is normally closed. The coil 254 is not electrically connected with the switches/contacts 252, 253. Of course, other electrical configurations are also possible.

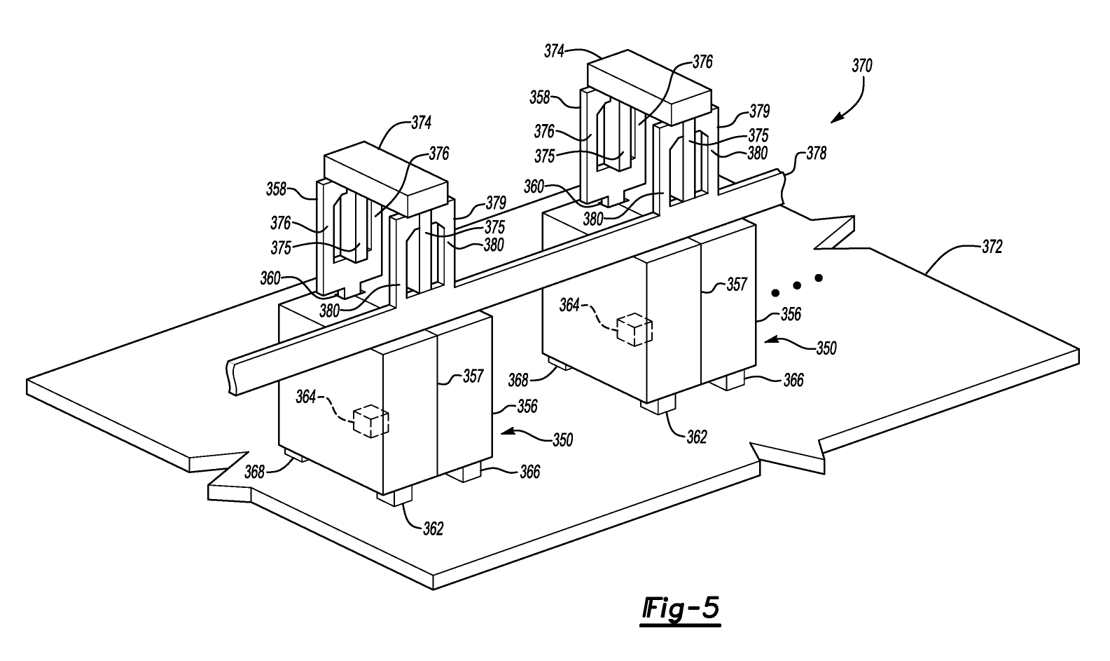

Referring now to FIG. 5, numbered elements that differ by 300 relative to the numbered elements of FIG. 1 have similar, although not necessarily identical, descriptions to the numbered elements of FIG. 1. An embodiment of an automotive printed circuit board assembly 370 may include a printed circuit board 372 and a plurality of integrated relay systems 350 aligned in a row(s). In other embodiments, the relay systems 350, however, may be positioned on the printed circuit board 372 as desired.

In the embodiment of FIG. 5, the housings 356 of the relay systems 350 have a two-piece configuration. During manufacture of the relay systems 350, the two-piece housings 356 are snapped together to encase a switch/contacts and coil (not shown). A seam 357 on each of the housings 356 results. Any suitable housing configuration, however, may be used.

Each of the relay systems 350 are electrically connected with the printed circuit board 372 via connector pins 362, 364, 366, 368.

In the embodiment of FIG. 5, an electrical bus bar 378 rests on the housings 356 and may be electrically connected with an electrical source and/or sink (not shown), etc. In other embodiments, the electrical bus bar 378 may be routed above (and spaced away from) the housings 356. Support members (not shown), for example, attached with and extending away from the printed circuit board 372 may be used to locate/hold/etc. the electrical bus bar 378 in such configurations. In still other embodiments, the housings 356 may include a feature (not shown), e.g., a trough, valley, etc., configured to locate/retain the electrical bus bar 378 on the housings 356. In such embodiments, the electrical bus bar 378 may include complimentary features that further locate/retain the electrical bus bar 378 on the housings 356. Other suitable arrangements are, of course, also possible.

The electrical bus bar 378 includes terminal interface portions 379. Each of the terminal interface portions 379 includes prong portions 380. As explained below, the prong portions 380 may retain, for example, a blade of a fuse.

The electrical bus bar 378 of FIG. 5 is stamped from a single piece of metal. In other embodiments, however, the terminal interface portions 379 may be formed separately and attached, e.g., welded, to form the electrical bus bar 378. Other configurations are also possible.

For each of the relay systems 350, a fuse 374 having blade portions 375 may be electrically connected with the interface terminal 358 and the electrical bus bar 378. Of course, other suitably configured fuses 374 may be used. In the embodiment of FIG. 5, the blade portions 375 are retained by prong portions 376 of the terminal interface 358 and prong portions 380 of the terminal interface portion 379. Other configurations, however, are also possible.

As apparent to those of ordinary skill, each of the relay systems 350 occupies less area of the printed circuit board 372 relative to, for example, the relay 10 and forked terminals 30, 32 illustrated in FIG. 2 because the interface terminals 358 are integral to the relay systems 350.

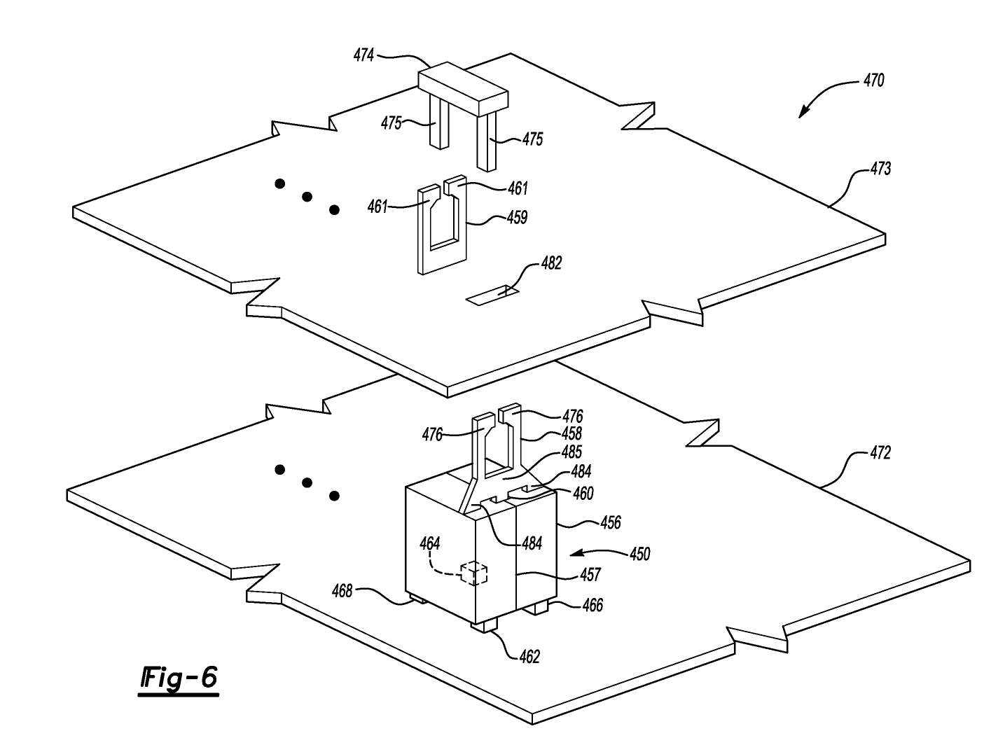

Referring now to FIG. 6, numbered elements that differ by 100 relative to the numbered elements of FIG. 5 have similar, although not necessarily identical, descriptions to the numbered elements of FIG. 5. Another embodiment of an automotive printed circuit board assembly 470 may include a pair of printed circuit boards 472, 473, an integrated relay system 450 electrically connected with the printed circuit board 472 and a terminal interface 459 electrically connected with the printed circuit board 473. Of course, additional relay systems 450 and terminal interfaces 459 may be included and positioned as desired.

The printed circuit board 473 includes a surface that defines an opening 482 configured to receive, as explained below, a terminal interface 458 of the relay system 450.

The terminal interfaces 458, 459 include respective prong portions 476, 461 each configured to receive and retain a blade portion 475 of a fuse 474. The terminal interface 458 further includes shoulder portions 484 that flare out from a bottom of the prong portions 476. In the embodiment of FIG. 6, the shoulder portions 484 contact the housing 456 and may reduce, for example, stresses on the terminal interface 458 when the blade portion 475 is inserted into or removed from the terminal interface 458. In other embodiments, the shoulder portions 484 may, for example, be formed on and extend away from surface 485 of the terminal interface 458. Other configurations are also possible.

During assembly of the printed circuit board assembly 470 of FIG. 6, the prong portions 476 of the terminal interface 458 are inserted through the opening 482 so that the terminal interface 458 is adjacent to the terminal interface 459. The housing 456 is thus sandwiched between the printed circuit boards 472, 473. The blade portions 475 of the fuse 474 are then inserted into the prong portions 461, 476 to electrically connect the terminal interfaces 458, 459. In embodiments having multiple relay systems 450 and terminal interfaces 459, an electrical bus bar (not shown), such as the electrical bus bar 378 illustrated in FIG. 5, may be used to electrically connect the terminal interfaces 458 associated with some or all of the relay systems 450.

As apparent to one of ordinary skill, the configuration described with reference to FIG. 6 may reduce the number of pins that run between the printed circuit boards 472, 473 and the number and size of associated circuit board traces relative to conventional stacked printed circuit board configurations.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. An integrated relay system for use with a fuse comprising:
an automotive relay including switching contacts and a casing, the casing at least partially surrounding the switching contacts and having a surface defining an aperture; and
a terminal interface electrically connected with at least one of the switching contacts and configured to receive a portion of the fuse, the terminal interface extending through the aperture and away from the casing.

2. The system of claim 1 wherein the terminal interface comprises a female terminal.

3. The system of claim 2 wherein the female terminal includes a pronged portion to retain the portion of the fuse and a shoulder portion adjacent to the casing to support the pronged portion.

4. The system of claim 1 wherein the switching contacts are configured to be electrically connected with a printed circuit board.

5. The system of claim 1, wherein the casing has another surface defining another aperture, further comprising another terminal interface electrically connected with one of the switching contacts and configured to receive another portion of the fuse, the another terminal interface passing through the another aperture and extending away from the casing.

6. The system of claim 5 wherein the terminal interfaces are disposed on a same side of the casing.

7. The system of claim 1 wherein the terminal interface comprises a forked terminal.

8. The system of claim 1 further comprising an electrical bus bar electrically connected with the terminal interface.

9. A printed circuit board assembly comprising:
first and second printed circuit boards;
a fuse;
an integrated relay system including
an automotive relay including (i) switching contacts electrically connected with the first printed circuit board and (ii) a casing at least partially surrounding the switching contacts and having a surface defining an aperture, and
a first terminal interface electrically connected with at least one of the switching contacts and configured to receive a portion of the fuse, the first terminal interface extending through the aperture and away from the casing, the second printed circuit board including a surface defining an opening configured to receive the first terminal interface, the first terminal interface extending though the opening; and
a second terminal interface attached to the second printed circuit board and configured to receive another portion of the fuse, the fuse connected with the first and second terminal interfaces.

10. The assembly of claim 9 wherein the casing is sandwiched between the first and second printed circuit boards.

11. The assembly of claim 9 wherein the first terminal interface comprises a forked terminal.

12. The assembly of claim 11 wherein the forked terminal includes a pronged portion to retain the portion of the fuse and a shoulder portion adjacent to the casing to support the pronged portion.

13. The assembly of claim 9 wherein the first terminal interface comprises a female terminal.

14. The assembly of claim 9 further comprising an electrical bus bar electrically connected with at least one of the terminal interfaces.

15. A printed circuit board assembly comprising:
a printed circuit board; and
a plurality of integrated relay systems attached with the printed circuit board, each of the plurality of integrated relay systems including
an automotive relay including (i) switching contacts electrically connected with the first printed circuit board and (ii) a casing at least partially surrounding the switching contacts and having a surface defining an aperture, and
at least one terminal interface electrically connected with at least one of the switching contacts and configured to receive a fuse, the at least one terminal interface passing through the aperture and extending away from the casing.

16. The assembly of claim 15 further comprising an electrical bus bar electrically connected with at least one of the terminal interfaces.

17. The assembly of claim 15 further comprising a plurality of fuses each being electrically connected with at least one of the terminal interfaces.

18. The assembly of claim 15 wherein at least one of the terminal interfaces comprises a female terminal.

19. The assembly of claim 18 wherein the female terminal includes a pronged portion and a shoulder portion.

20. The assembly of claim 18 wherein the female terminal comprises a forked terminal.
